(19) United States
(12) Patent Application Publication
(10) Pub. No.: US 2026/0202749 A1
(43) Pub. Date: Jul. 16, 2026

(54) COMPOSITION FOR PHOTORESIST REMOVAL AND METHOD FOR REMOVING PHOTORESIST

(71) Applicant: MITSUBISHI GAS CHEMICAL COMPANY, INC., Tokyo (JP)

(72) Inventors: Shin-ya KUROSAWA, Ashigarakami-gun, Kanagawa (JP); Takashi SUGIMOTO, Ashigarakami-gun, Kanagawa (JP); Masami SONE, Ashigarakami-gun, Kanagawa (JP); Satoshi TAMAI, Ashigarakami-gun, Kanagawa (JP); Yoshiki MIYASHITA, Ashigarakami-gun, Kanagawa (JP)

(73) Assignee: MITSUBISHI GAS CHEMICAL COMPANY, INC., Tokyo (JP)

(21) Appl. No.: 19/136,969

(22) PCT Filed: Dec. 12, 2023
(86) PCT No.: PCT/JP2023/044366

§ 371 Date: Jun. 9, 2025

(30) Foreign Application Priority Data
Dec. 12, 2022 (JP) 2022-198227

(51) Int. Cl. G03F 7/42; G03F 7/30; H05K 3/00; H10P 50/68; H10W 20/44

(52) U.S. Cl. CPC G03F 7/425; G03F 7/30; H05K 3/0079; H10P 50/68; H10W 20/4421

(57) ABSTRACT

The present invention can provide a composition for removing a photoresist, which is for forming a copper-containing pattern, after the pattern has been formed, including:
an alkaline agent containing at least one selected from the group consisting of an alkanolamine, a quaternary ammonium hydroxide, and an inorganic alkali;
an organic solvent having Hansen solubility parameter coordinates that are within an area of a sphere centered on δd=16.0, δp=8.7, δh=15.5 within a radius of 3.60 MPa0.5 or less, and
an azole compound.

### TECHNICAL FIELD

The present invention relates to a composition for photoresist removal and a method for removing a photoresist using the same and so on.

### BACKGROUND ART

In recent years, electronic devices are becoming smaller and more functional, and the printed wiring boards used in such electronic devices are also required to become smaller and more functional.

In order to produce a printed wiring board and the like that satisfies such a demand, a method such as the following is adopted. For example, a metal layer called a seed layer is formed on an insulating layer that contains copper wiring in a portion thereof. A photoresist layer is formed on the surface of the seed layer, and the photoresist is exposed and developed to form a resist pattern. Then, copper plating is applied to the openings of the pattern, and the photoresist and seed layer are then removed to form a circuit pattern that serves as a connection terminal portion of the copper wiring.

As described above, methods for producing a printed wiring board and the like often include a step of removing a photoresist, and in the photoresist removal step, an aqueous solution containing various components is usually used (for example, Patent Literature 1).

### CITATION LIST

### Patent Literature

Patent Literature 1: International Publication No. 2020/022491

### SUMMARY OF INVENTION

### Technical Problem

In a conventional production process of a printed wiring board and the like, there are cases where the photoresist is not removed quickly and sufficiently enough. If the photoresist could be removed quickly and reliably, the printed wiring board productivity could be improved.

Further, when a conventional processing solution is used in the step of removing the photoresist, there is a possibility of the members that are ultimately needed, such as the copper plating, being damaged.

In light of the above, there is a need for a technique that has an excellent performance in removing a photoresist as a part of the production process for printed wiring boards and the like, and can also reliably protect members that contain copper such as copper plating.

### Solution to Problem

The present invention includes, for example, the following aspects.
[1]A composition for removing a photoresist, which is for forming a copper-containing pattern, after the pattern has been formed, including:
   an alkaline agent containing at least one selected from the group consisting of an alkanolamine, a quaternary ammonium hydroxide, and an inorganic alkali;
   an organic solvent having Hansen solubility parameter coordinates that are within an area of a sphere centered on δd=16.0, δp=8.7, δh=15.5 within a radius of 3.60 MPa^{0.5} or less; and an azole compound.
[2] The composition according to the above [1], wherein the organic solvent has Hansen solubility parameter coordinates that are within the area of the sphere centered on δd=16.0, δp=8.7, δh=15.5 within a radius of 3.00 MPa^{0.5} or less.
[3] The composition according to the above [1], wherein the organic solvent includes at least one selected from the group consisting of ethylene glycol monomethyl ether, methylhydrazine, 2,2,2-trifluoroethanol, diacetin, 1-chloro-2-propanol, dimethylaminoethanol, ethylenediamine, 1,9-nonanediol, 2-bromoallyl alcohol, 2,3-dichloropropanol, furfuryl alcohol, adipic acid, ethylene chlorohydrin. N-formylethylamine, ethylene glycol monopropyl ether, 2-chloro-2-propen-1-ol, 1-(2-hydroxyethyl)-2-pyrrolidone, diethylene glycol monovinyl ether, diethylenetriamine, 1,3-dichloro-2-propanol, 2-ethoxyethanol, 3-chloro-2-propen-1-ol, serotonin, 1,6-hexanediol, 2-cyclopenten-1-ol, methylamine, formic acid, ethylene glycol monoisopropyl ether, 3-azidopropene, 2,3-butadien-1-ol, allyl alcohol, 2-fluoropropenoic acid, acetic acid, azidoethane, isocyanic acid, n-propanol, (E)-2-buten-1-ol, methyl salicylate, 2-propanol, L-(−)-tyrosine, dipropylene glycol, ethyl carbamate, and 2,2-dimethyl-1-propanol.
[4] The composition according to the above [1], wherein an etching rate of copper is less than 0.05 μm/min.
[5] The composition according to the above [1], which is water-soluble.
[6] The composition according to the above [1], wherein the composition includes, based on a total amount of the composition, 3.0 to 50% by mass of the alkaline agent, 0.1 to 30% by mass of the organic solvent, and 0.001 to 1.0% by mass of the azole compound.
[7] The composition according to the above [1], wherein the pattern is a circuit pattern that serves as a connection terminal portion of copper wiring formed on an insulating layer having the copper wiring in at least a part thereof.
[8] A method for removing a photoresist, including a photoresist removal step of bringing the composition according to any one of the above [1] to [7] into contact with a photoresist for forming a copper-containing pattern.
[9] The method for removing a photoresist according to the above [8], wherein the pattern is a circuit pattern that serves as a connection terminal portion of copper wiring formed on an insulating layer having the copper wiring in at least a part thereof.
[10] A method for producing a printed wiring board, a semiconductor element, or a semiconductor package, including a photoresist removal step of bringing the composition according to any one of the above [1] to [7] into contact with a photoresist for forming a copper-containing pattern.
[11] The method for producing a printed wiring board, a semiconductor element, or a semiconductor package according to the above [10], wherein the pattern is a circuit pattern that serves as a connection terminal portion of copper wiring formed on an insulating layer having the copper wiring in at least a part thereof.

### Advantageous Effects of Invention

According to the present invention, a composition for photoresist removal is provided that can efficiently remove a photoresist and can reliably protect members that contain copper such as copper plating in a printed wiring board.

### DESCRIPTION OF EMBODIMENTS

The composition of the present invention can be preferably used to remove a photoresist after the formation of a copper-containing pattern, and contains at least a specific alkaline agent, organic solvent, and azole compound. The composition will now be described in detail below.

### [I. Composition]

The composition is preferably water-soluble. That is, it is preferred that at least a part of the composition can dissolve or is suspendable in water, and it is more preferred that the composition can be uniformly mixed with water in any ratio.

In addition, it is preferred that at least a part of the components other than water contained in the composition can dissolve in water, and it is more preferred that the components other than water contained in the composition and water can be mixed uniformly.

### <1-1. (A) Alkaline Agent>

The composition preferably contains 3.0 to 50% by mass of an alkaline agent (A) (hereinafter also referred to as component (A)) based on the total mass of the composition. The content of the alkaline agent in the composition is, based on the total mass of the composition, more preferably 4.0 to 40% by mass, further preferably 5.0 to 30% by mass or 6.0 to 35% by mass, and particularly preferably 7.0 to 15% by mass, 8.0 to 20% by mass, or 9.0 to 12% by mass.

A composition containing the component (A) can have effects such as good removability of the photoresist and suppressed damage to a circuit pattern that includes copper, a copper alloy, or the like, which serves as a connection terminal portion of the copper wiring.

The alkaline agent (A) preferably contains at least any of (A-1) an alkanolamine, (A-2) a quaternary ammonium hydroxide, and (A-3) an inorganic alkali, more preferably contains two of these, and particularly preferably contains all of (A-1) to (A-3).

### (A-1) Alkanolamine

The type of the (A-1) alkanolamine that may be contained in the composition as the component (A) is not particularly limited, and examples may include a monoalkanolamine, a dialkanolamine, a trialkanolamine, or an alkylated product (N-alkylated product, O-alkylated product) thereof.

Preferred examples of the alkanolamine (A) include 2-aminoethanol (monoethanolamine), N-methylethanolamine, N-ethylethanolamine, N-propylethanolamine, N-butylethanolamine, diethanolamme, 1-amino-2-propanol (isopropanolamine), N-methylisopropanolamine, N-ethylisopropanolamine, N-propylisopropanolamine, 2-aninopropan-1-ol, N-methyl-2-amino-propan-1-ol, N-ethyl-2-amino-propan-1-ol, 1-aminopropan-3-ol, N-methyl-1-aminopropan-3-ol, N-ethyl-1-aminopropan-3-ol, 1-aminobutan-2-ol, N-methyl-1-aminobutan-2-ol, N-ethyl-1-aminobutan-2-ol, 2-aminobutan-1-ol, N-methyl-2-aminobutan-1-ol, N-ethyl-2-aminobutan-1-ol, 3-aminobutan-1-ol, N-methyl-3-aminobutan-1-ol, N-ethyl-3-aminobutan-1-ol, 1-aminobutan-4-ol, N-methyl-1-aminobutan-4-ol, N-ethyl-1-aminobutan-4-ol, 1-amino-2-methylpropan-2-ol, 2-amino-2-methylpropan-1-ol, I-aminopentan-4-ol, 2-amino-4-methylpentan-1-ol, 2-aminohexane-1-ol, 3-aminoheptan-4-ol, 1-aminooctan-2-ol, 5-aminooctan-4-ol, 1-aminopropane-2,3-diol, 2-aminopropane-1,3-diol, tris(oxymethyl)aminomethane, 1,2-diaminopropan-3-ol, 1,3-diaminopropan-2-ol, 2-(2-aminoethoxy)ethanol, and the like. These may be used alone or in combination of two or more.

Among these, the alkanolamine is preferably one or more selected from the group consisting of 2-aminoethanol (monoethanolamine) and 1-amino-2-propanol.

The content of the alkanolamine is, based on the total amount of the composition, preferably 1.0 to 50% by mass, more preferably 1.5 to 45% by mass, 1.5 to 42% by mass, 2.0 to 30% by mass or 2.0 to 15% by mass, further preferably 3.0 to 12% by mass, and particularly preferably 4.0 to 8.0% by mass or 5.0 to 9.0% by mass.

### (A-2) Quaternary Ammonium Hydroxide

The type of the (A-2) quaternary ammonium hydroxide that may be contained in the composition as the component (A) is not particularly limited, and examples include tetramethylammonium hydroxide, tetraethylammonium hydroxide, tetrapropylammonium hydroxide, triethylmethylammonium hydroxide, ethyltrimethylammonium hydroxide, trimethyl(2-hydroxyethyl)ammonium hydroxide, and triethyl(2-hydroxyethyl)ammonium hydroxide. These may be used alone or in combination of two or more.

Among these, the quaternary ammonium hydroxide is preferably one or more selected from the group consisting of tetramethylammonium hydroxide, tetraethylammonium hydroxide, and triethylmethylammonium hydroxide.

The content of the quaternary ammonium hydroxide is, based on the total amount of the composition, preferably 0.3 to 12% by mass, more preferably 0.5 to 10% by mass, further preferably 1.0 to 8.0% by mass, and particularly preferably 1.5 to 5.0% by mass or 2.0 to 6.0% by mass.

### (A-3) Inorganic Alkali

The type of the inorganic alkali (A-3) that may be contained in the composition as the component (A) is not particularly limited, and examples include an alkali metal compound such as lithium hydroxide, sodium hydroxide, potassium hydroxide, sodium carbonate, potassium carbonate, sodium silicate, and potassium silicate; an alkaline earth metal compound such as magnesium hydroxide, calcium hydroxide, magnesium carbonate, calcium carbonate, calcium silicate, and magnesium silicate; a transition metal compound such as copper hydroxide and iron hydroxide; ammonia, and the like.

Of these, potassium hydroxide, sodium hydroxide, and the like are preferred as the inorganic alkali.

The content of the inorganic alkali is preferably, based on the total amount of the composition, 0.001 to 5.0% by mass, more preferably 0.01 to 3.0% by mass, further preferably 0.05 to 2.0% by mass, and particularly preferably 0.1 to 0.5% by mass or 0.2 to 1.0% by mass.

### <I-2. (B) Organic Solvent>

The composition preferably contains 0.1 to 30.0% by mass of the (B) organic solvent (hereinafter also referred to as component (B)) based on the total mass of the composition. The content of the organic solvent in the composition is, based on the total mass of the composition, more preferably 0.5 to 25% by mass, further preferably 1.0 to 20% by mass or 1.5 to 15% by mass, and particularly preferably 2.0 to 10% by mass, 2.2 to 5.0% by mass, or 2.5 to 4.0% by mass.

The composition contains at least an organic solvent (hereinafter also referred to as a specific organic solvent) that has Hansen solubility parameter (HSP) coordinates that are within the area of a sphere centered on a point (hereinafter also referred to as the center point) δd=16.0, δp=8.7, δh=15.5 within a radius of 3.60 MPa^{0.5}, that is, an organic solvent having a distance from the center point of the HSP coordinates of 3.60 MPa-5 or less. Thus, in a composition containing an organic solvent having HSP values with a small distance from the center point of the coordinates, there is found to be an effect of improving the removability of the photoresist, in particular, an effect of improving the performance of efficiently stripping the photoresist from the metal layer rather than dissolving in aqueous solution. The expression for calculating the distance from the center point is shown below.

$$Distance from center point = \sqrt{{( δ d - 16.0 )}^{2} + {( δ p - 8.7 )}^{2} + {( δ h - 15.5 )}^{2}}$$

The reason why there is found to be an effect of stripping and removing the resist is, for example, as follows. A specific organic solvent that has HSP values close to the distance from the center point of the HSP coordinates will tend to have low compatibility with the components of the photoresist such as a dry film, which is described in detail later, and will probably have a poor action in terms of dissolving the photoresist. However, the specific organic solvent can promote the contact of the alkaline agent and water with the photoresist such as the dry film, and can facilitate a reaction of the alkaline agent with the terminal carboxy group of the photoresist. This action of the specific organic solvent can cause a neutralization reaction between the terminal carboxy group of the photoresist and the alkaline agent, and facilitate infiltration of the aqueous solution between the photoresist and the metal layer, thereby causing the photoresist to swell. As a result, the swollen photoresist can be easily stripped from the metal layer covering the surface.

Thus, it is believed that the specific organic solvent having the characteristic HSP values can remove a photoresist more efficiently than an organic solvent having different HSP values which acts by dissolving the photoresist. This is because a relatively long time is required to dissolve the photoresist in a solution, whereas a composition that is able to easily infiltrate the gap between the photoresist and the metal layer covered by the photoresist can strip away and remove the photoresist by just acting on a more limited range of the photoresist.

It is preferred that the specific organic solvent have a distance from the center point of the HSP coordinates of 3.30 MPa^{0.5} or less, more preferably 3.00 MPa^{0.5} or less, and further preferably 2.70 MPa^{0.5}. A specific organic solvent having a distance from the center point of the HSP coordinates of 2.50 MPa^{0.5} or less, 2.30 MPa^{0.5} or less, 2.00 MPa^{0.5} or less, 1.50 MPa^{0.5} or less, or 1.00 MPa^{0.5} or less may be used. Further, a specific organic solvent having a distance from the center point of the HSP coordinates of 0.70 MPa^{0.5} to 3.50 MPa^{0.5}, 1.00 MPa^{0.5} to 3.30 MPa^{0.5}, 1.50 MPa^{0.5} to 3.00 MPa^{0.5}, 2.00 MPa^{0.5} to 2.70 MPa^{0.5}, and the like may be used.

Preferred specific examples of the specific organic solvent include the following, and Table 1 shows the compound names, HSP coordinates, and distance from the central point of those specific examples.

First, examples of the specific organic solvent having a distance from the central point of the HSP coordinates of 1.50 MPa^{0.5} or less include ethylene glycol monomethyl ether, methylhydrazine, a trifluoroethanol such as 2,2,2-trifluoroethanol, diacetin, a chloropropanol such as 1-chloro-2-propanol, and the like.

Examples of the specific organic solvent having a distance from the central point of the HSP coordinates of more than 1.50 MPa and 3.00 Mpa^{0.5} or less include dimethylaminoethanol, ethylenediamine, a nonanediol such as 1,9-nonanediol, a bromoallyl alcohol such as 2-bromoallyl alcohol, a dichloropropanol such as 2,3-dichloropropanol, furfuryl alcohol, adipic acid, ethylene chlorohydrin. N-formylethylamine, ethylene glycol monopropyl ether, a chloroallyl alcohol such as 2-chloroallyl alcohol (2-chloro-2-propen-1-ol), a 2-pyrrolidone having a 2-hydroxyethyl group such as 1-(2-hydroxyethyl)-2-pyrrolidone, diethylene glycol monovinyl ether, diethylenetriamine, a dichloropropanol such as 1,3-dichloro-2-propanol, an ethoxyethanol such as 2-ethoxyethanol, a chloroallyl alcohol such as 3-chloro-2-propen-1-ol, serotonin, a hexanediol such as 1,6-hexanediol, a cyclopentenol such as 2-cyclopenten-1-ol, methylamine, formic acid, ethylene glycol monoisopropyl ether, an azidopropene such as 3-azidopropene, 2,3-butadiene-1-ol, allyl alcohol, a fluoropropenoic acid such as 2-fluoropropenoic acid, acetic acid, azidoethane, isocyanic acid, a propanol such as n-propanol, a butenol such as (E)-2-buten-1-ol, methyl salicylate, a propanol such as 2-propanol, L-(−)-tyrosine, dipropylene glycol, ethyl carbamate, 2,2-dimethyl-1-propanol, and the like.

In addition, examples of the specific organic solvent having a distance from the central point of the HSP coordinates of more than 3.00 MPa^{0.5} and 3.60 Mpa^{0.5} or less include 4′-hydroxyacetanilide, 1-butanol, 1-methoxymethanol, diethylene glycol monomethyl ether, 3-hydroxytetrahydrofuran, isobutyl alcohol, 2-butanol, ethyl lactate, triethylene glycol monomethyl ether, tetrahydrofurfuryl alcohol, 2-pentanol, glycerol formal, 1-aminocyclopropanecarboxylic acid, 1-pentanol, glycidol, 2-propyn-1-ol, 1,2-cyclohexanediol, diethylene glycol monoethyl ether, isooctyl alcohol, 3-chloro-1-propanol, 2-methyl-2-butanol, salicylic acid, 3-methoxy-3-methylbutanol, coniferyl alcohol, sinapyl alcohol, acetone cyanohydrin, crotonic acid, and the like.

TABLE 1

| | | | | Distance | | | | | Distance |
|---|---|---|---|---|---|---|---|---|---|
| | | | | from center | | | | | from center |
| | | | | point | | | | | point |
| Organic solvent | δD | δP | δH | [MPa^{0.5}] | Organic solvent | δD | δP | δH | [MPa^{0.5}] |
| ethylene glycol monomethyl | 16.0 | 8.2 | 15.0 | 0.71 | n-propanol | 16.0 | 6.8 | 17.4 | 2.69 |
| ether | | | | | | | | | |
| methylhydrazine | 16.2 | 8.7 | 14.8 | 0.73 | (E)-2-buten-1-o1 | 16.0 | 6.0 | 15.5 | 2.70 |
| 2,2,2-trifluoroethanol | 15.4 | 8.3 | 16.4 | 1.15 | methyl salicylate | 18.1 | 8.0 | 13.9 | 2.73 |
| diacetin | 16.4 | 8.9 | 14.2 | 1.37 | 2-propanol | 15.8 | 6.1 | 16.4 | 2.76 |
| 1-chloro-2-propanol | 16.8 | 9.8 | 15.3 | 1.37 | L-(-)-tyrosine (Tyrosine) | 17.5 | 6.9 | 17.2 | 2.89 |
| dimethylaminoethanol | 16.1 | 9.2 | 14.0 | 1.58 | dipropylene glycol | 16.5 | 10.6 | 17.7 | 2.95 |
| ethylenediamine | 16.6 | 8.8 | 17.0 | 1.62 | ethyl carbamate | 16.8 | 10.1 | 13.0 | 2.97 |
| 1,9-nonanediol | 15.7 | 7.0 | 15.1 | 1.77 | 2,2-dimethyl-1-propanol | 15.6 | 6.5 | 13.5 | 3.00 |
| 2-bromoallyl alcohol | 17.1 | 9.9 | 16.2 | 1.77 | 4′-hydroxyacetanilide | 17.8 | 10.5 | 13.9 | 3.01 |
| 2,3-dichloropropanol | 17.5 | 9.2 | 14.6 | 1.82 | 1-butanol | 16.0 | 5.7 | 15.8 | 3.01 |
| furfuryl alcohol | 17.4 | 7.6 | 15.1 | 1.82 | 1-methoxymethanol | 16.0 | 9.0 | 18.5 | 3.01 |
| adipic acid | 17.1 | 10.0 | 16.3 | 1.88 | diethylene glycol | 16.2 | 7.8 | 12.6 | 3.04 |
| | | | | | monomethyl ether | | | | |
| ethylene chlorohydrin | 16.9 | 8.8 | 17.2 | 1.93 | 3-hydroxytetrahydrofuran | 18.9 | 9.4 | 16.3 | 3.09 |
| N-formylethylamine | 16.2 | 10.0 | 14.0 | 1.99 | isobutyl alcohol | 15.1 | 5.7 | 15.9 | 3.16 |
| ethylene glycol monopropyl | 16.1 | 8.7 | 13.5 | 2.00 | 2-butanol | 15.8 | 5.7 | 14.5 | 3.17 |
| ether | | | | | | | | | |
| 2-chloro-2-propen-1-ol | 17.1 | 10.2 | 16.4 | 2.07 | ethyl lactate | 16.0 | 7.6 | 12.5 | 3.20 |
| 1-(2-hydroxyethyl)-2- | 18.0 | 9.2 | 15.7 | 2.07 | triethylene glycol | 16.2 | 7.6 | 12.5 | 3.20 |
| pyrrolidone | | | | | monomethyl ether | | | | |
| diethylene glycol monovinyl | 16.3 | 7.5 | 13.8 | 2.10 | tetrahydrofurfuryl alcohol | 17.8 | 8.2 | 12.9 | 3.20 |
| ether | | | | | | | | | |
| diethylenetriamine | 16.7 | 7.1 | 14.3 | 2.12 | 2-pentanol | 15.6 | 6.4 | 13.3 | 3.21 |
| 1,3-dichloro-2-propanol | 17.5 | 9.9 | 14.6 | 2.12 | glycerol formal | 18.4 | 10.6 | 16.5 | 3.22 |
| 2-ethoxyethanol | 15.9 | 7.2 | 14.0 | 2.12 | 1-aminocyclopropanecarboxylic | 17.0 | 6.3 | 13.6 | 3.22 |
| | | | | | acid | | | | |
| 3-chloro-2-propen-1-ol | 17.2 | 10.3 | 16.5 | 2.24 | 1-pentanol | 15.9 | 5.9 | 13.9 | 3.23 |
| serotonin | 18.0 | 8.2 | 14.4 | 2.34 | glycidol | 18.2 | 9.0 | 17.9 | 3.27 |
| 1,6-hexanediol | 15.7 | 8.4 | 17.8 | 2.34 | 2-propyn-1-ol | 16.1 | 8.7 | 18.8 | 3.30 |
| 2-cyclopenten-1-ol | 18.1 | 7.6 | 15.6 | 2.37 | 1,2-cyclohexanediol | 17.4 | 9.8 | 18.3 | 3.32 |
| methylamine | 14.4 | 7.0 | 16.0 | 2.39 | diethylene glycol monoethyl | 16.1 | 9.2 | 12.2 | 3.34 |
| | | | | | ether | | | | |
| formic acid | 14.6 | 10.0 | 14.0 | 2.43 | isooctyl alcohol | 14.4 | 7.3 | 12.9 | 3.36 |
| ethylene glycol | 16.0 | 8.2 | 13.1 | 2.45 | 3-chloro-1-propanol | 17.5 | 5.7 | 14.7 | 3.45 |
| monoisopropyl ether | | | | | | | | | |
| 3-azidopropene | 16.8 | 7.7 | 13.4 | 2.46 | 2-methyl-2-butanol | 15.3 | 6.1 | 13.3 | 3.48 |
| 2,3-butadien-1-ol | 16.2 | 6.6 | 16.8 | 2.48 | salicylic acid | 19.0 | 9.0 | 13.7 | 3.51 |
| allyl alcohol | 16.2 | 10.8 | 16.8 | 2.48 | 3-methoxy-3-methylbutanol | 16.0 | 6.3 | 12.9 | 3.54 |
| 2-fluoropropenoic acid | 16.0 | 8.7 | 13.0 | 2.50 | coniferyl alcohol | 19.0 | 7.0 | 16.3 | 3.54 |
| acetic acid | 14.5 | 8.0 | 13.5 | 2.60 | sinapyl alcohol | 19.2 | 7.3 | 16.1 | 3.54 |
| azidoethane | 15.9 | 8.9 | 12.9 | 2.61 | acetone cyanohydrin | 16.6 | 12.2 | 15.5 | 3.55 |
| isocyanic acid | 15.8 | 10.5 | 13.6 | 2.62 | crotonic acid | 16.8 | 8.7 | 12.0 | 3.59 |

Of the above-described specific examples, the specific organic solvent included in the composition is, from the viewpoint of availability and the like, more preferably ethylene glycol monopropyl ether (distance from the center point of 2.00 MPa^{0.5}), n-propanol (distance from the center point 2.69 MPa^{0.5}), and the like.

One type of the specific organic solvent may be used, or two or more types may be used. Further, the component (B) organic solvent in the composition may include an organic solvent other than the specific organic solvent. However, it is preferred that the organic solvent in the composition contains, based on the total amount of the organic solvent, 30% by mass or more of the specific organic solvent, more preferably 50% by mass or more of the specific organic solvent, further preferably 70% by mass or more of the specific organic solvent, and particularly preferably 90% by mass or more of the specific organic solvent. It is still further preferred that the specific organic solvent is the only organic solvent contained in the composition.

### <I-3. (C) Azole Compound>

The composition preferably contains 0.001 to 1.0% by mass of the (C) azole compound (hereinafter also referred to as component (C)) based on the total mass of the composition. The content of the azole compound in the composition is, based on the total mass of the composition, more preferably 0.005 to 0.80% by mass, further preferably 0.01 to 0.60% by mass or 0.015 to 0.70% by mass, and particularly preferably 0.02 to 0.40% by mass, 0.025 to 0.50% by mass, or 0.03 to 0.30% by mass.

A composition containing the component (C) can have effects such as protecting a metal layer containing copper or a copper alloy and reducing the etching rate of copper.

The azole compound in the composition preferably contains at least any of a triazole compound, an imidazole compound, a benzimidazole compound, and a pyrazole compound.

The triazole compound is not particularly limited as long as it is a compound having a triazole ring, and examples include a triazole which may be 1,2,3-triazole or 1,2,4-triazole, a triazole that has a substituent having 10 or less carbon atoms, a triazole such as tolyltriazole having an aromatic ring fused to the triazole ring, and triazole salts of these.

The imidazole compound is not particularly limited as long as it is a compound having an imidazole ring, and examples thereof include imidazole, an imidazole derivative that has a substituent having 10 or less carbon atoms, for example, a 1-alkylimidazole such as 1-methylimidazole, a 4-alkylimidazole such as 4-methylimidazole, a mercapto-imidazole such as 2-mercapto-imidazole, and imidazolium salts of these.

The benzimidazole compound is not particularly limited as long as it is a compound having a benzimidazole skeleton, and examples thereof include benzimidazole, a benzimidazole derivative that has a substituent having 10 or less carbon atoms, such as 1-alkylbenzimidazole, 2-alkylbenzimidazole, 7-alkylbenzimidazole, and a benzimidazolium salts of these.

Further, examples of the pyrazole compound include pyrazole, a pyrazole that has a substituent having 10 or less carbon atoms, a 1-alkylpyrazole such as 1-methylpyrazole, a 3-alkylpyrazole such as 3-methylpyrazole, a 4-alkylpyrazole such as 4-methylpyrazole, a 5-alkylpyrazole such as 5-methylpyrazole, and pyrazole salts of these.

### <I-4. Water>

The composition preferably contains water. There are no particular limitations on the type of water contained in the composition, but it is preferred that metal ions, organic impurities, particles, and the like have been removed by, for example, distillation, an ion exchange treatment, filtration, or some kind of adsorption treatment. It is more preferred to use pure water, and particularly preferred to use ultrapure water.

The water content in the composition is, based on the total amount of the composition, preferably 20% by mass or more, more preferably more than 20% by mass, and more preferably in the range of 20 to 99% by mass, further preferably 40 to 97% by mass, still further preferably 60 to 95% by mass, and particularly preferably 70 to 95% by mass. In a composition in which the water content has been adjusted in this way, reactivity with the photoresist and removability of the photoresist are improved.

### <I-5. Other Components>

The composition may contain other secondary components as necessary, as long as the components do not impair the above-described effects. Examples of other components include a pH adjuster, a surfactant, a defoamer, and the like. For example, an organic acid (organic acid ion), an ammonium ion, or the like may be added. Adding an organic acid or an organic acid ion to the composition improves the affinity of the composition to the dry film resist. Adding an ammonium ion to the composition improves the reactivity of the composition to the carboxyl group of the dry film resist.

Further, carbonate ions, or a carbonate, bicarbonate, and the like that generates carbonate ions, may be added to the composition. Adding carbonate ions and the like to the composition improves copper corrosion protection. Specific examples of the carbonate or bicarbonate include salts of ammonium ions, salts of alkali metals or alkaline earth metals, and the like.

An organic acid ammonium salt such as ammonium benzoate or an ammonium carbonate such as tetramethylammonium carbonate or the like may be added to the composition in combination with the above-described components.

The content of secondary components in the composition is, based on the total amount of the composition, preferably 10% by mass or less, more preferably 5.0% by mass or less, more preferably 3.0% by mass or less, further preferably 2.0% by mass or less, or 1.5% by mass or less.

Further, the content of each salt component that generates an organic acid (organic acid ions), ammonium ions, carbonate ions in the composition is preferably 5.0% by mass or less, more preferably 3.0% by mass or less, further preferably 2.0% by mass or less, or 1.5% by mass or less.

It is noted that the composition is preferably a solution, and preferably does not contain solid particles such as abrasive particles.

### <I-6. Method for Preparing the Composition>

The composition of the present invention is prepared by adding the component (A), the component (B), the component (C), water, and, if necessary, other components, and stirring preferably until the mixture becomes completely uniform. In producing the composition, the order of adding and mixing each component is not particularly limited. For example, a small amount of water may be added to the component (A) such as any of the components (A-1) to (A-3), the components other than water may be prepared as concentrated solutions, and the components may be mixed at the site where the composition is to be used. The composition may also be prepared by transporting any of the components in such a concentrated state, that is, in a state not containing water, and adding water.

### <I-7. Properties of the Composition>

The pH range of the composition of the present invention is not particularly limited, but in one aspect, the pH value of the composition is 8 or more, preferably 10 or more, and more preferably 11 or more. The pH value can be measured by a general method using a pH meter.

The composition of the present invention makes it possible to suppress damage to copper and copper alloys. As a result, it becomes possible to suppress a copper etching rate, which is evaluated by the method described in detail below in the Examples section, to 0.050 μm/min or less. More preferably, the copper etching rate as evaluated by the method described in detail below is 0.040 μm/min or less, further preferably 0.030 μm/min or less, and particularly preferably 0.020 μm/min or 0.015 μm/min or less.

The composition of the present invention can effectively remove a photoresist. As a result, it may become possible to set an L.P. (lifting point) value relating to a stripping rate, which is evaluated by the method described in detail below in the Examples section, to 100 seconds or less. More preferably, the L.P, value as evaluated by the method described in detail below is 90 seconds or less, further preferably 85 seconds or less, and particularly preferably 80 seconds or less or 75 seconds or less.

### <I-8. Use of the Composition>

There are no particular limitations on the temperature at which the composition is used to remove a photoresist, but a temperature of 10 to 70° C. is preferred, more preferably 20 to 65° C., and further preferably 25 to 60° C. Using the composition within this temperature range improves the removability of the photoresist, and also makes it easier to maintain the removal conditions of the photoresist by suppressing compositional changes in the composition.

There are no particular limitations on the processing time of the photoresist with the composition, but the processing time is preferably 20 to 600 seconds, more preferably 30 to 300 seconds, and may be 30 to 240 seconds. The processing time is the time the composition is in contact with the photoresist, and may be appropriately selected depending on various conditions such as the surface state of the photoresist to be removed, the concentration of the composition, the temperature, and the processing method.

There are no particular limitations on the method for bringing the composition of the present invention into contact with the photoresist. For example, methods such as a method wherein the composition of the present invention is brought into contact with the photoresist to be removed by dropping (single-wafer spin processing) or spraying or the like, or a method wherein the photoresist to be removed is immersed in the composition of the present invention, may be adopted. Either method may be adopted in the present invention.

### <II. Method for Removing Photoresist>

The photoresist removal method of the present invention includes a photoresist removal step in which the composition of the present invention is brought into contact with a photoresist for forming a copper-containing pattern. The method for removing the photoresist is described below.

The composition of the present invention can be suitably used, for example, when removing a photoresist for forming, on an insulating layer having copper wiring in at least a part thereof, a copper-containing circuit pattern that serves as a connection terminal portion of the copper wiring after the circuit pattern has been formed.

Herein, the “insulating layer having the copper wiring in at least a part thereof” is not particularly limited as long as the layer is an insulating layer having copper wiring on a surface or embedded inside. Examples include a silicon insulating layer of a printed wiring board, a package substrate for mounting a semiconductor element, a semiconductor wafer, and the like.

Further, the “copper-containing circuit pattern that serves as a connection terminal portion of the copper wiring” is, for example, a circuit pattern that serves as a connection terminal portion of the copper wiring in the insulating layer for making an electrical connection with other components.

In one embodiment of the present invention, the connection terminal portion is a connection terminal portion of copper wiring in a printed wiring board. Further, in one embodiment of the present invention, the connection terminal portion is a connection terminal portion of copper wiring in a package substrate for mounting a semiconductor element. In addition, in one embodiment of the present invention, the connection terminal portion is a connection terminal portion of copper wiring in a semiconductor element.

### <III. Method for Producing Printed Wiring and the Like>

The method for producing a printed wiring of the present invention includes a photoresist removal step in which the composition of the present invention is brought into contact with a photoresist for forming a copper-containing pattern. In addition to a printed wiring board, the composition of the present invention can also be suitably used in the photoresist removal step of a method for producing a semiconductor element and a semiconductor package.

For example, the composition of the present invention can be suitably used when, in the production process of a printed wiring board (for example, a package substrate for mounting a semiconductor element), removing a photoresist for forming, on an insulating layer having copper wiring in at least a part thereof, a copper-containing circuit pattern that serves as a connection terminal portion of the copper wiring after the circuit pattern has been formed.

In addition, the composition of the present invention can be suitably used in the production process of a semiconductor element when removing a photoresist for forming, on an insulating layer having copper wiring in at least a part thereof, a circuit pattern that includes copper and at least one selected from the group consisting of tin and a tin alloy, which serves as a connection terminal portion of the copper wiring, after the circuit pattern is formed.

Examples of the photoresist used for a printed wiring board include a composition containing a binder polymer, a photopolymerizable monomer, a photopolymerization initiator, and other additives.

Examples of the binder polymer include those obtained by copolymerizing several types of vinyl monomers, such as a methacrylic acid ester, an acrylic acid ester, and styrene, with at least one of methacrylic acid and acrylic acid as an essential component.

Preferred photopolymerizable monomers include at least one of a methacrylic acid ester and an acrylic acid ester.

Examples of the photopolymerization initiator include at least one from the group consisting of benzophenone, 4,4′-diaminobenzophenone, 4,4′-bis(dimethylamino)benzophenone, 2-ethylanthraquinone, benzoin, benzoin methyl ether, 9-phenylacridine, benzyl dimethyl ketal, and benzyl diethyl ketal. Further, a bimolecular system consisting of a hexaarylbiimidazole and a hydrogen donor (2-mercaptobenzoxazal, N-phenylglycine) may also be used.

Examples of the other additives include a thermal polymerization initiator and a dye.

Examples of a preferred photoresist for use in a semiconductor element include a combination of a phenol-formaldehyde resin (collectively known as “novolac resins”) and a naphthoquinone diazide compound, which is a photosensitive component.

Examples of the resist arranged between the metal wires include a dry film resist, a liquid resist, and the like. Of these, the resist is preferably a dry film resist. There are no particular limitations on the dry film resist, but a dry film resist made of a photosensitive resin is preferred. Examples of the photosensitive resin include a negative photosensitive resin and a positive photosensitive resin.

Examples of the negative photosensitive resin include, but are not limited to, an azide-based photosensitive resin, a diazo-based photosensitive resin, an acetylenic low molecular weight photosensitive resins, an ethylenic low molecular weight photosensitive resin, an insolubilized polymer-based photosensitive resin, and a chromate-based photosensitive resin. These negative photosensitive resins may be used alone or in combination of two or more.

Examples of the positive photosensitive resin include, but are not limited to, a quinone diazide-based photosensitive resin, a solubilized polymer-based photosensitive resin, and the like. These positive photosensitive resins may be used alone or in combination of two or more.

Of these, the dry film resist is preferably formed from a negative photosensitive resin. Negative photosensitive resins undergo curing in the exposure process during pattern formation, and become insoluble in the developer, and so the exposed portions (the portions where the negative photosensitive resin has been cured) remain as the dry film resist. During exposure, curing tends to proceed particularly at the surface portion of the negative photosensitive resin that is exposed, and the surface portion of the resulting dry film resist can have a particularly dense structure. As a result, even if an attempt is made to remove the dry film resist using a composition, the composition may have difficulty penetrating into the interior of the dry film resist. Further, some compositions may not have sufficient resist removal ability, and removal of the dry film resist may not proceed. As a result, it may take a long time to remove the dry film resist.

In contrast, the composition of the present invention easily penetrates the dry film resist, allowing the dry film resist to be stripped off and removed quickly.

### EXAMPLES

### (Preparation of Sample for Evaluating Stripping Properties)

A sample for evaluating stripping properties was prepared as follows. First, a copper-clad laminate (CCL-HL832NS (MT-FL) 0.1 mmtC/C, manufactured by MITSUBISHI GAS CHEMICAL COMPANY, INC.) was chemically plated with copper to form a thin copper film (thickness: 1.0 μm). A dry film resist (RD-3025, manufactured by Showa Denko K.K., thickness: 25 μm) was attached to the surface of the thin copper film, a circuit mask pattern was formed thereon, and exposure and development were carried out. The dry film resist was exposed and developed to form a circuit pattern opening, which was then electrolytically plated with copper (thickness: 17 μm) to obtain a sample for evaluating stripping properties. The pattern of the dry film resist formed on the sample for evaluating stripping properties was a pattern of dots of 100 to 300 μm in diameter.

### (Preparation of Sample for Evaluating Copper Corrosion Resistance)

A sample for evaluating copper corrosion resistance was prepared as follows. That is, the surface of a copper-clad laminate (CCL-HL832NX, manufactured by MITSUBISHI GAS CHEMICAL COMPANY, INC.) was electrolytically plated with copper (thickness: 35 μm) to obtain a sample for evaluating copper corrosion resistance.

### (Stripping Rate (L.P. (Lifting Point)))

The aqueous compositions described in the examples and comparative examples were brought into contact with the above-described sample for evaluating stripping properties by spraying at a spray pressure of 0.15 MPa at 50° C.

Then, the time from when the aqueous composition was sprayed to when the dry film resist was completely stripped from the substrate of the sample for evaluating stripping properties was measured, and taken as the L.P. (seconds). In measuring the L.P., the solid portion on the periphery of the sample, and not the dot pattern portion formed on the sample for evaluating stripping properties, was visually observed, and the point at which the dry film resist had been removed was taken as the time.

### (Copper Corrosion Resistance (Cu E.R. (Etching Rate)))

The sample for evaluating copper corrosion resistance cut into a 4 cm×4 cm square was brought into contact with the aqueous composition described in the examples and comparative examples by spraying the aqueous composition at a spray pressure of 0.15 MPa at 50° C. for 5 minutes. Next, the sample for evaluating copper corrosion resistance was cleaned with pure water, cleaned with 5% by mass sulfuric acid, then cleaned with pure water, after which the sample for evaluating copper corrosion resistance was thoroughly dried.

The value of the Cu E.R. (μm/min) was calculated as follows. Specifically, the mass of the sample for evaluating copper corrosion resistance before and after the above-described spraying treatment with the aqueous composition was measured, the etched thickness was calculated from the mass difference, the copper density (8.93 g/cm³), and the sample size (treated area [cm²]; it is noted that since the back side of the sample for evaluating copper corrosion resistance was protected with masking tape, the treated area is the area of the surface of the sample), and the etching amount per minute was determined based on the following expression (I).

$$Cu E . R . [ \frac{μm}{min} ] = \frac{\begin{matrix}sample mass [ g ] before treatment - \\ sample mass [ g ] after treatment\end{matrix}}{\begin{matrix}sample area [ {cm}^{2} ] \times 8.93 [ \frac{g}{{cm}^{3}} ] \times \\ sample time [ min ]\end{matrix}} \times {10}^{4} \qquad ( 1 )$$

### (Stripping Properties)

The above sample for evaluating stripping properties was brought into contact with the aqueous compositions described in the examples and comparative examples by spraying the aqueous composition at a spray pressure of 0.15 MPa at 50° C. for 3 minutes. The samples were then cleaned with pure water, cleaned with 5% by mass sulfuric acid, cleaned again with pure water, and then thoroughly dried.

The stripping properties was evaluated as follows. Using an optical microscope (MX-61L, manufactured by Olympus Corporation, objective lens 50×), residues of the dry film resist on the samples for evaluating stripping properties that had been sprayed with the aqueous composition as described above were checked, and evaluated according to the following criteria.
Particularly good: All samples had 5 or less residues of dry film resist 100 to 300 μm in diameter.
Good: All samples had 110 or less residues of dry film resist 100 to 300 μm in diameter.
Poor: Some samples had more than 110 residues of dry film resist 100 to 300 μm in diameter.

### Example 1

An aqueous composition was prepared by adding monoethanolamine (MEA) in an amount that would ultimately be 6% by mass (32 g of 75% MEA aqueous solution), tetramethylammonium hydroxide (TMAH) in an amount that would ultimately be 4% by mass (64 g of 25% TMAH aqueous solution), potassium hydroxide (KOH) in an amount that would ultimately be 0.3% by mass (2.4 g of 50% KOH aqueous solution), ethylene glycol monopropyl ether in an amount that would ultimately be 2% by mass (8.0 g), tolyltriazole in an amount that would ultimately be 0.09% by mass (0.36 g), ammonium benzoate in an amount that would ultimately be 1.5% by mass (6.0 g), and tetramethylammonium bicarbonate (TMBC) in an amount that would ultimately be 11% by mass (44 g) respectively, to 243 g of pure water. The L.P. of the resulting aqueous composition was 60 sec, the Cu E.R. was 0.007 μm/min, and the stripping properties were particularly good.

It is noted that tetramethylammonium bicarbonate can be generated as a degradation product of tetramethylammonium hydroxide, and can reduce the stripping performance of the dry film resist produced by the aqueous composition. For this reason, in order to evaluate the stripping treatment by the aqueous composition when tetramethylammonium bicarbonate is generated by long-term use, the bicarbonate was added to the aqueous compositions of those examples.

The properties and evaluation results of the aqueous compositions are shown in Table 2 below.

### Examples 2 to 5 and Comparative Examples 1 to 8

Aqueous compositions were prepared and evaluation tests were performed in the same manner as in Example 1, except that either the type or amount of the various components in the composition of Example 1 was changed as shown in Table 2 below. The properties and evaluation results of the aqueous compositions of each example and comparative example are shown in Table 2 below.

Table 2 shows the distance from the center point (δd=16, δp=8.7, δh=15.5) of the coordinates of the Hansen solubility parameters of the organic solvent contained in the aqueous composition of each example and comparative example, and Table 3 shows the position of the organic solvent of the coordinates of the Hansen solubility parameters in more detail.

TABLE 2

| | Components of Composition [% by mass] | | | | | | | | | | |
|---|---|---|---|---|---|---|---|---|---|---|---|
| | (A) Alkaline agent | | | | | | (B) Organic solvent | | | | |
| | (A-1) | | (A-2) | | (A-3) | | | | Distance from | (C) Azole compound | |
| | Compound name | | Compound name | | Compound name | | Compound name | | center point | Compound name | |
| | [% by mass] | | [% by mass] | | [% by mass] | | [% by mass] | | [MPa^{0.5}] | [% by mass] | |
| Example 1 | MEA | 6 | TMAH | 4 | KOH | 0.3 | ethylene glycol | 2 | 2.00 | TTZ | 0.09 |
| | | | | | | | monopropyl ether | | | | |
| Example 2 | MEA | 6 | TMAH | 3 | KOH | 0.3 | n-propanol | 2 | 2.69 | TTZ | 0.09 |
| Example 3 | MEA | 6 | TMAH | 3 | KOH | 0.3 | ethylene glycol | 2 | 2.00 | 3-MPZ | 0.20 |
| | | | | | | | monopropyl ether | | | | |
| Example 4 | MEA | 6 | TMAH | 3 | KOH | 0.3 | ethylene glycol | 2 | 2.00 | 3-MPZ | 0.20 |
| | | | | | | | monopropyl ether | | | | |
| Example 5 | MEA | 6 | TMAH | 3 | KOH | 0.3 | ethylene glycol | 2 | 2.00 | 3-MPZ | 0.20 |
| | | | | | | | monopropyl ether | | | | |
| Comparative | MEA | 6 | TMAH | 3 | KOH | 0.3 | — | — | — | TTZ | 0.09 |
| Example 1 | | | | | | | | | | | |
| Comparative | MEA | 8 | TMAH | 4 | KOH | 0.3 | — | — | — | TTZ | 0.09 |
| Example 2 | | | | | | | | | | | |
| Comparative | MEA | 8 | TMAH | 4 | KOH | 0.3 | cyclohexylamine | 2 | 10.67 | TTZ | 0.09 |
| Example 3 | | | | | | | | | | | |
| Comparative | MEA | 6 | TMAH | 3 | KOH | 0.3 | ethylene carbonate | 2 | 16.77 | TTZ | 0.09 |
| Example 4 | | | | | | | | | | | |
| Comparative | MEA | 6 | TMAH | 3 | KOH | 0.3 | ethanol | 2 | 3.91 | TTZ | 0.09 |
| Example 5 | | | | | | | | | | | |
| Comparative | MEA | 8 | TMAH | 8 | — | — | ethylene glycol | 4 | 3.70 | 1,2,4-TRZ | 0.16 |
| Example 6 | | | | | | | monophenyl ether | | | | |
| Comparative | MEA | 8 | TMAH | 8 | — | — | ethylene glycol | 4 | 3.70 | 1,2,4-TRZ | 0.16 |
| Example 7 | | | | | | | monophenyl ether | | | | |
| Comparative | MEA | 8 | TMAH | 8 | — | — | ethylene glycol | 4 | 3.70 | 1,2,4-TRZ | 0.16 |
| Example 8 | | | | | | | monophenyl ether | | | | |

| | Components of Composition [% by mass] | | | | Evaluation results | | | | | | | |
|---|---|---|---|---|---|---|---|---|---|---|---|---|
| | Aging agent | | Other | | | | | Stripping residues [number] | | | | |
| | Compound name | | Compound name | | L.P. | Cu E.R. | | 300 | 250 | 200 | 150 | 100 |
| | [% by mass] | | [% by mass] | | [sec] | [μm/min] | Strippability | μm | μm | μm | μm | μm |
| Example 1 | TMBC | 11 | ammonium | 1.5 | 60 | 0.007 | particularly | 0 | 0 | 3.5 | 2 | 0 |
| | | | benzoate | | | | good | | | | | |
| Example 2 | TMBC | 11 | ammonium | 1.5 | 68 | 0.010 | good | 0 | 0.5 | 36 | 23 | 0 |
| | | | benzoate | | | | | | | | | |
| Example 3 | — | — | ammonium | 1.5 | 46 | 0.004 | particularly | 0 | 0 | 0 | 0.5 | 0 |
| | | | benzoate | | | | good | | | | | |
| Example 4 | TMBC | 7 | ammonium | 1.5 | 54 | 0.004 | particularly | 0 | 0.5 | 1 | 0.5 | 0 |
| | | | benzoate | | | | good | | | | | |
| Example 5 | TMBC | 11 | ammonium | 1.5 | 82 | 0.004 | particularly | 0 | 0 | 1 | 0 | 0 |
| | | | benzoate | | | | good | | | | | |
| Comparative | TMBC | 11 | ammonium | 1.5 | 87 | 0.010 | good | 2 | 1.5 | 46.5 | 34.5 | 1.5 |
| Example 1 | | | benzoate | | | | | | | | | |
| Comparative | TMBC | 11 | ammonium | 2.0 | 73 | 0.010 | poor | 3 | 2.5 | 1 | 67.5 | 122.5 |
| Example 2 | | | benzoate | | | | | | | | | |
| Comparative | TMBC | 11 | ammonium | 2.0 | 76 | 0.020 | good | 1 | 1 | 20.5 | 2.5 | 0 |
| Example 3 | | | benzoate | | | | | | | | | |
| Comparative | TMBC | 11 | ammonium | 1.5 | 142 | 0.020 | good | 3.5 | 0.5 | 8.5 | 0.5 | 0 |
| Example 4 | | | benzoate | | | | | | | | | |
| Comparative | TMBC | 11 | ammonium | 1.5 | 85 | 0.002 | good | 1.5 | 2 | 3.5 | 63.5 | 1.5 |
| Example 5 | | | benzoate | | | | | | | | | |
| Comparative | — | — | — | — | 56 | 0.060 | particularly | 0 | 0 | 0 | 0 | 0 |
| Example 6 | | | | | | | good | | | | | |
| Comparative | TMBC | 7 | — | — | 73 | 0.050 | poor | 0 | 0 | 0 | 0 | 113 |
| Example 7 | | | | | | | | | | | | |
| Comparative | TMBC | 11 | — | — | 89 | 0.050 | poor | 0 | 0 | 0 | 0 | 114 |
| Example 8 | | | | | | | | | | | | |

(Abbreviations in the table)
Alkaline agent
MEA: monoethanolamine = 2-aminoethanol
TMAH: tetramethylammonium hydroxide
Azole compound
TTZ: triyltriazole
3-MPZ: 3-methylpyrazole
1,2,4-TRZ: 1,2,4-triazole
Aging agent
TMBC: tetromethylammonium bicarbonate
Evaluation results
L.P.: lifting point
E.R.: etching rate

TABLE 3

| | | | | Distance from |
|---|---|---|---|---|
| | | | | center point |
| Organic solvent | δd | δp | δh | [MPa^{0.5}] |
| ethylene glycol | 16.1 | 8.7 | 13.5 | 2.00 |
| monopropyl ether | | | | |
| n-propanol | 16 | 6.8 | 17.4 | 2.69 |
| cyclohexylamine | 17.2 | 3.1 | 6.5 | 10.67 |
| ethylene carbonate | 18 | 21.7 | 5.1 | 16.77 |
| ethanol | 15.8 | 8.8 | 19.4 | 3.91 |
| ethylene glycol | 17.8 | 5.7 | 14.3 | 3.70 |
| monophenyl ether | | | | |

As is clear from the above results, it was confirmed that, according to the aqueous compositions of the examples containing organic solvents close to the center point (δd=16, δp=8.7, δh=15.5) of the coordinates of the Hansen solubility parameters (see the column “Distance from center point [MPa^{0.5}]” in Table 2 and Table 3), the time indicated by the L.P. (lifting point) value was shorter than that of the aqueous compositions of the comparative examples, the photoresist could be stripped more quickly, and generation of a resist residue could be suppressed. In addition, the Cu E.R. (etching rate) value tended to be lower in the examples than in the comparative examples, and the results showed that the copper corrosion resistance was excellent.

1: A composition for removing a photoresist, which is for forming a copper-containing pattern, after the pattern has been formed, the composition comprising:
an alkaline agent comprising at least one selected from the group consisting of an alkanolamine, a quaternary ammonium hydroxide, and an inorganic alkali;
an organic solvent having Hansen solubility parameter coordinates that are within an area of a sphere centered on δd=16.0, δp=8.7, δh=15.5 within a radius of 3.60 MPa^{0.5} or less; and
an azole compound.

2: The composition according to claim 1, wherein the organic solvent has Hansen solubility parameter coordinates that are within the area of the sphere centered on δd=16.0, δp=8.7, δh=15.5 within a radius of 3.00 MPa^{0.5} or less.

3: The composition according to claim 1, wherein the organic solvent includes at least one selected from the group consisting of ethylene glycol monomethyl ether, methylhydrazine, 2,2,2-trifluoroethanol, diacetin, 1-chloro-2-propanol, dimethylaminoethanol, ethylenediamine, 1,9-nonanediol, 2-bromoallyl alcohol, 2,3-dichloropropanol, furfuryl alcohol, adipic acid, ethylene chlorohydrin, N-formylethylamine, ethylene glycol monopropyl ether, 2-chloro-2-propen-1-ol, 1-(2-hydroxyethyl)-2-pyrrolidone, diethylene glycol monovinyl ether, diethylenetriamine, 1,3-dichloro-2-propanol, 2-ethoxyethanol, 3-chloro-2-propen-1-ol, serotonin, 1,6-hexanediol, 2-cyclopenten-1-ol, methylamine, formic acid, ethylene glycol monoisopropyl ether, 3-azidopropene, 2,3-butadien-1-ol, allyl alcohol, 2-fluoropropenoic acid, acetic acid, azidoethane, isocyanic acid, n-propanol, (E)-2-buten-1-ol, methyl salicylate, 2-propanol, L-(−)-tyrosine, dipropylene glycol, ethyl carbamate, and 2,2-dimethyl-1-propanol.

4: The composition according to claim 1, wherein an etching rate of copper is less than 0.05 μm/min.

5: The composition according to claim 1, which is water-soluble.

6: The composition according to claim 1, comprising, based on a total amount of the composition, 3.0 to 50% by mass of the alkaline agent, 0.1 to 30% by mass of the organic solvent, and 0.001 to 1.0% by mass of the azole compound.

7: The composition according to claim 1, wherein the pattern is a circuit pattern that serves as a connection terminal portion of copper wiring formed on an insulating layer having the copper wiring in at least a part thereof.

8: A method for removing a photoresist, the method comprising:
bringing the composition according to claim 1 into contact with the photoresist for forming the copper-containing pattern.

9: The method according to claim 8, wherein the pattern is a circuit pattern that serves as a connection terminal portion of copper wiring formed on an insulating layer having the copper wiring in at least a part thereof.

10: A method for producing a printed wiring board, a semiconductor element, or a semiconductor package, the method comprising:
bringing the composition according to claim 1 into contact with Ibg photoresist for forming the copper-containing pattern.

11. The method according to claim 10, wherein the pattern is a circuit pattern that serves as a connection terminal portion of copper wiring formed on an insulating layer having the copper wiring in at least a part thereof.
